(19) United States
(12) Patent Application Publication
(10) Pub. No.: US 2016/0172437 A1
(43) Pub. Date: Jun. 16, 2016

(54) Wide Band Gap Semiconductor Device

(71) Applicant: SUMITOMO ELECTRIC INDUSTRIES, LTD., Osaka-shi (JP)

(72) Inventor: Takeyoshi Masuda, Osaka-shi (JP)

(21) Appl. No.: 14/908,474

(22) PCT Filed: Jun. 13, 2014
(86) PCT No.: PCT/JP2014/065713

§ 371 Date: Jan. 28, 2016

(30) Foreign Application Priority Data
Aug. 1, 2013 (JP) 2013-160608

(51) Int. Cl. H01L 29/06; H01L 29/20; H01L 29/78; H01L 29/16

(52) U.S. Cl. CPC H01L 29/0619; H01L 29/1608; H01L 29/2003; H01L 29/1602; H01L 29/7811; H01L 29/7813

(57) ABSTRACT

A semiconductor substrate (epitaxial substrate) having a main surface (upper surface) and made of a wide band gap semiconductor is provided, the semiconductor substrate including a device region formed in the semiconductor substrate, and a peripheral region formed to surround the device region. In the peripheral region, the semiconductor substrate includes a first semiconductor region (drift layer) having a first conductivity type, and a second semiconductor region (electric field relaxing region) formed on the first semiconductor region (drift layer) and having the main surface, the second semiconductor region having a second conductivity type different from the first conductivity type, and a plurality of trenches annularly surrounding the device region are formed in the main surface of the second semiconductor region (electric field relaxing region). Consequently, a wide band gap semiconductor device capable of achieving a higher breakdown voltage is provided without an increase in size.

### TECHNICAL FIELD

The present invention relates to wide band gap semiconductor devices, and more particularly to a wide band gap semiconductor device having a peripheral region.

### BACKGROUND ART

In recent years, silicon carbide has been increasingly employed as a material forming a semiconductor device such as a MOSFET (Metal Oxide Semiconductor Field Effect Transistor) in order to allow for higher breakdown voltage, lower loss, the use in a high-temperature environment and the like of the semiconductor device. Silicon carbide is a wide band gap semiconductor having a band gap wider than that of silicon which has been conventionally and widely used as a material forming a semiconductor device. By employing the silicon carbide as a material forming a semiconductor device, therefore, higher breakdown voltage, lower on-resistance and the like of the semiconductor device can be achieved. A semiconductor device made of silicon carbide is also advantageous in that performance degradation is small when used in a high-temperature environment as compared to a semiconductor device made of silicon.

One of known methods to achieve a higher breakdown voltage of a semiconductor device is to provide a plurality of guard rings concentrically to surround an element region, with the impurity concentration decreasing toward outer guard ring regions.

Japanese Patent Laying-Open No. 2011-44688 describes a semiconductor device having a peripheral region (terminal region) in which a plurality of p type guard rings are formed at a distance from an active region. Each guard ring is a floating guard ring formed in a surface layer portion of an epitaxial layer, and is covered with a gate insulating film and an interlayer insulating film.

### CITATION LIST

### PATENT DOCUMENT

PTD 1: Japanese Patent Laying-Open No. 2011-44688

### SUMMARY OF INVENTION

### Technical Problem

In order to achieve an even higher breakdown voltage of the semiconductor device using the guard ring structure described in Japanese Patent Laying-Open No. 2011-44688, however, the size of the peripheral region (terminal region) in which the guard rings are formed needs to be increased. In this case, in order to maintain the size of a semiconductor element region (device region), the size of the semiconductor device itself needs to be increased. Unfortunately, such increase in size of the semiconductor device results in increased costs to manufacture the semiconductor device.

The present invention has been made to solve the problem as described above. A main object of the present invention is to provide a wide band gap semiconductor device capable of achieving a higher breakdown voltage without an increase in size.

### Solution to Problem

A wide band gap semiconductor device according to the present invention includes a semiconductor substrate having a main surface and made of a wide band gap semiconductor, the semiconductor substrate including a device region formed in the semiconductor substrate, and a peripheral region formed to surround the device region, in the peripheral region, the semiconductor substrate including a first semiconductor region having a first conductivity type, and a second semiconductor region formed on the first semiconductor region and having the main surface, the second semiconductor region having a second conductivity type different from the first conductivity type, a plurality of trenches annularly surrounding the device region being formed in the main surface of the second semiconductor region.

### Advantageous Effects of Invention

According to the present invention, a wide band gap semiconductor device capable of achieving a higher breakdown voltage can be provided without an increase in size.

### BRIEF DESCRIPTION OF DRAWINGS

FIG. 1 is a cross-sectional view of a wide band gap semiconductor device according to a first embodiment.

FIG. 2 is a cross-sectional view illustrating a method of manufacturing the wide band gap semiconductor device according to the first embodiment.

FIG. 3 is a cross-sectional view illustrating the method of manufacturing the wide band gap semiconductor device according to the first embodiment.

FIG. 4 is a cross-sectional view illustrating the method of manufacturing the wide band gap semiconductor device according to the first embodiment.

FIG. 5 is a cross-sectional view illustrating the method of manufacturing the wide band gap semiconductor device according to the first embodiment.

FIG. 6 is a cross-sectional view illustrating the method of manufacturing the wide band gap semiconductor device according to the first embodiment.

FIG. 7 is a cross-sectional view illustrating the method of manufacturing the wide band gap semiconductor device according to the first embodiment.

FIG. 8 is a cross-sectional view of a wide band gap semiconductor device according to a second embodiment.

FIG. 9 is a cross-sectional view of a wide band gap semiconductor device according to a first reference example.

FIG. 10 is a cross-sectional view illustrating a method of manufacturing the wide band gap semiconductor device according to the first reference example.

FIG. 11 is a cross-sectional view illustrating the method of manufacturing the wide band gap semiconductor device according to the first reference example.

FIG. 12 is a cross-sectional view illustrating the method of manufacturing the wide band gap semiconductor device according to the first reference example.

FIG. 13 is a cross-sectional view illustrating the method of manufacturing the wide band gap semiconductor device according to the first reference example.

FIG. 14 is a cross-sectional view illustrating the method of manufacturing the wide band gap semiconductor device according to the first reference example.

FIG. 15 is a cross-sectional view illustrating the method of manufacturing the wide band gap semiconductor device according to the first reference example.

FIG. 16 is a cross-sectional view of a variation of the wide band gap semiconductor device according to the first embodiment.

FIG. 17 is a cross-sectional view of a variation of the wide band gap semiconductor device according to the first embodiment.

### DESCRIPTION OF EMBODIMENTS

Embodiments of the present invention will be described below with reference to the drawings. In the following drawings, the same or corresponding parts are designated by the same reference numbers and description thereof will not be repeated. Regarding crystallographic denotation herein, an individual orientation, a group orientation, an individual plane, and a group plane are shown in [ ], < >, ( ) and { }, respectively. Although a crystallographically negative index is normally expressed by a number with a bar “-” thereabove, a negative sign herein precedes a number to indicate a crystallographically negative index. In expressing an angle, a system in which a total azimuth angle is defined as 360 degrees is employed.

### Description of Embodiments of the Present Invention

A summary of embodiments of the present invention will be initially described.

(1) A wide band gap semiconductor device according to this embodiment includes a semiconductor substrate (epitaxial substrate 20) having a main surface (upper surface P2) and made of a wide band gap semiconductor, semiconductor substrate 20 including a device region 20E formed in semiconductor substrate 20, and a peripheral region 20T formed to surround device region 20E. In peripheral region 20T, semiconductor substrate 20 includes a first semiconductor region (drift layer 21) having a first conductivity type, and a second semiconductor region (electric field relaxing region 25) formed on the first semiconductor region (drift layer 21) and having main surface P2, the second semiconductor region having a second conductivity type different from the first conductivity type, and a plurality of peripheral region trenches 70 annularly surrounding device region 20E are formed in main surface P2 of the second semiconductor region (electric field relaxing region 25).

Consequently, since the plurality of peripheral region trenches 70 annularly surrounding device region 20E are formed in peripheral region 20T, a creepage distance of the main surface (upper surface P2) can be increased in a direction from device region 20E toward an outer peripheral end of the wide band gap semiconductor device. That is, the creepage distance of main surface P2 in peripheral region 20T can be increased without an increase in spatial distance of peripheral region 20T (the shortest straight-line distance from device region 20E to the outer peripheral end of the wide band gap semiconductor device). In this case, when a high voltage is applied to the wide band gap semiconductor device, a depletion layer is formed at an interface between the first semiconductor region and the second semiconductor region in peripheral region 20T. As a result, the wide band gap semiconductor device according to this embodiment can achieve a higher breakdown voltage without an increase in size.

(2) In the wide band gap semiconductor device according to this embodiment, a bottom of each of the peripheral region trenches (70) may be located at the second semiconductor region (25) side with respect to an interface between the first semiconductor region (21) and the second semiconductor region (25).

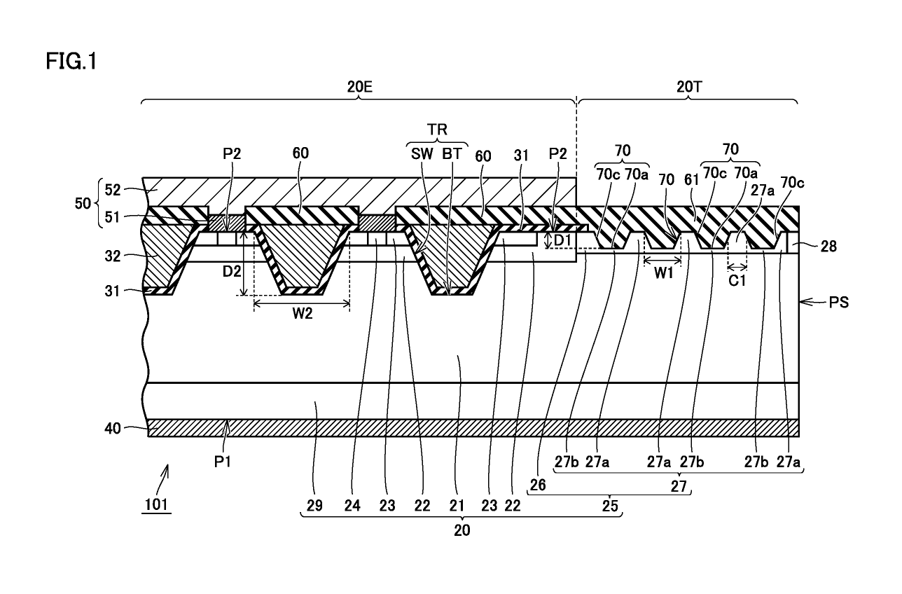

Again in this case, since the plurality of peripheral region trenches 70 are formed, the creepage distance of the main surface (upper surface P2) can be increased in the direction from device region 20E toward the outer peripheral end of the wide band gap semiconductor device. Further, the second semiconductor region (electric field relaxing region 25) is provided without being divided by peripheral region trenches 70. Accordingly, a depletion layer readily expands at the interface between the first semiconductor region (drift layer 21) and second semiconductor region 25, particularly in a direction parallel to main surface P2. As a result, electric field concentration can be effectively relaxed from device region 20E toward an outer peripheral end of peripheral region 20T, thereby improving the breakdown voltage of the wide band gap semiconductor device. Further, since second semiconductor region 25 is provided without being divided by peripheral region trenches 70, the entire second semiconductor region 25 (a JTE region 26 and a guard ring region 27 in FIG. 1) can be source-grounded by connecting second semiconductor region 25 to source region 23 on the side close to device region 20E, for example. As a result, when a voltage is applied between the source and drain (ON) and then the application of the voltage is stopped (OFF), for example, conductive ions (carriers) in second semiconductor region 25 can be quickly recovered immediately after the stopping. Thus, the ON operation can be effected again immediately after the OFF operation in a state where the conductive ions in second semiconductor region 25 have been reliably recovered, thereby suppressing characteristic variation during the ON operation.

(3) In the wide band gap semiconductor device according to this embodiment, a bottom of each of the peripheral region trenches (70) may be located at the first semiconductor region (21) side with respect to an interface between the first semiconductor region (21) and the second semiconductor region (25).

Again in this case, since the plurality of peripheral region trenches 70 are formed in peripheral region 20T, the creepage distance of the main surface (upper surface P2) can be increased without an increase in spatial distance of peripheral region 20T (the shortest straight-line distance from device region 20E to the outer peripheral end of the wide band gap semiconductor device). As a result, the wide band gap semiconductor device according to this embodiment can achieve a higher breakdown voltage without an increase in size.

(4) A dielectric layer covering peripheral region trenches 70 may be formed on the main surface (upper surface P2) of the second semiconductor region. Consequently, dielectric layer 61 can protect the second semiconductor region (electric field relaxing region 25), and more effectively relax electric field concentration on main surface P2 in peripheral region 20T.

(5) A material forming the dielectric layer may include at least one selected from the group consisting of silicon dioxide, polyimide, and silicon nitride. Again in this case, electric field concentration in the vicinity of device region 20E and in peripheral region 20T can be relaxed to improve the breakdown voltage of the wide band gap semiconductor device.

(6) In the device region of the wide band gap semiconductor device according to this embodiment, a device trench TR may be provided in main surface P2 of the semiconductor substrate (epitaxial substrate 20), a width of each of peripheral region trenches 70 at main surface P2 in a direction perpendicular to a direction in which peripheral region trench 70 extends (W1: FIG. 1) may be smaller than a width of device trench TR at main surface P2 in a direction perpendicular to a direction in which device trench TR extends (W2: FIG. 1), and a depth of each of peripheral region trenches 70 in a direction perpendicular to the main surface (upper surface P2) (D1: FIG. 1) may be smaller than a depth of device trench TR in the direction perpendicular to the main surface (upper surface P2) (D2: FIG. 1).

That is, in the trench type wide band gap semiconductor device in which device trench TR is formed in device region 20E, the width of peripheral region trench 70 in the direction perpendicular to the direction in which peripheral region trench 70 extends may be smaller than the width of device trench TR in the direction in which device trench TR extends. Further, the depth of peripheral region trench 70 in the direction perpendicular to the main surface (upper surface P2) may be smaller than the depth of device trench TR in the direction perpendicular to the main surface. Consequently, since the width and depth of peripheral region trench 70 are sufficiently small, a depletion layer expanding from the interface between the second semiconductor region (electric field relaxing region 25) and the first semiconductor region (drift layer 21) can be formed below peripheral region trench 70 as well. Accordingly, a depletion layer expanding over a large area can be formed in peripheral region 20T. As a result, electric field concentration in the vicinity of device region 20E and in peripheral region 20T can be relaxed to improve the breakdown voltage of the wide band gap semiconductor device.

(7) In the device region, the semiconductor substrate (epitaxial substrate 20) may include the first semiconductor region (drift layer 21) having the main surface (upper surface P2), a pair of third semiconductor regions (body regions 22) spaced apart from and facing each other at main surface P2, the third semiconductor regions having the second conductivity type, and a fourth semiconductor region (source region 23) having the first conductivity type in each of the pair of third semiconductor regions (body regions 22), a width of each of peripheral region trenches 70 at main surface P2 in a direction perpendicular to a direction in which peripheral region trench 70 extends may be smaller than spacing between the third semiconductor regions (p body regions 22) facing each other with the first semiconductor region interposed therebetween at main surface P2, and a depth of each of peripheral region trenches 70 in a direction perpendicular to the main surface may be smaller than a depth of a bottom of each of the third semiconductor regions (p body regions 22) from the main surface.

That is, in the planar type wide band gap semiconductor device, the width of peripheral region trench 70 in the direction perpendicular to the direction in which peripheral region trench 70 extends may be smaller than the spacing between the pair of third semiconductor regions (p body regions 22) facing each other with the first semiconductor region interposed therebetween. Further, the depth of peripheral region trench 70 in the direction perpendicular to the main surface (upper surface P2) may be smaller than the depth of the bottom of third semiconductor region 22 from the main surface. Consequently, since the width and depth of peripheral region trench 70 are sufficiently small, a depletion layer expanding from the interface between the second semiconductor region (electric field relaxing region 25) and the first semiconductor region (drift layer 21) can be formed below peripheral region trench 70 as well. Accordingly, a depletion layer expanding over a large area can be formed in peripheral region 20T. As a result, electric field concentration in the vicinity of device region 20E and in peripheral region 20T can be relaxed to improve the breakdown voltage of the wide band gap semiconductor device.

(8) A sidewall of each of peripheral region trenches 70 may be inclined with respect to main surface P2. In this case, the second semiconductor region (electric field relaxing region 25) can reduce the spacing between thick portions 27a more on the side close to the interface with the first semiconductor region (drift layer 21) than on the side close to main surface P2. Thus, particularly when the second semiconductor region (electric field relaxing region 25) is divided into a plurality of portions by peripheral region trench 70, depletion layers extending from an interface between each thick portion 27a and first semiconductor region 21 can be readily expanded so that they are connected together by extending over peripheral region trench 70. Further, peripheral region trench 70 having the sidewall inclined with respect to main surface P2 can be formed by forming a trench having a sidewall perpendicular to main surface P2 by dry etching, for example, then removing by wet etching or the like a process damaged layer generated by the dry etching. This can suppress the occurrence of variation in the way a depletion layer expands due to the formation of a process damaged layer in second semiconductor region 25.

(9) The first conductivity type may be n type, and the second conductivity type may be p type. Again in this case, a pn junction surface is formed at the interface between the first semiconductor region (drift layer 21) having the first conductivity type and the second semiconductor region (electric field relaxing region 25) having the second conductivity type. Thus, a depletion layer can be formed in peripheral region 20T to improve the breakdown voltage of the wide band gap semiconductor device.

It is noted that in the wide band gap semiconductor device according to this embodiment, the semiconductor substrate may be an epitaxial substrate in which an epitaxial layer is formed on a base substrate such as a single-crystal substrate, or may be an epitaxial layer in which a base substrate has been removed from an epitaxial substrate.

### Details of Embodiments of the Present Invention

The embodiments of the present invention will now be described in more detail.

### First Embodiment

Referring to FIG. 1, a wide band gap semiconductor device according to a first embodiment is described. A MOSFET 101 as an example of the wide band gap semiconductor device according to the first embodiment is a trench gate type transistor. MOSFET 101 has an epitaxial substrate 20 (semiconductor substrate), a gate oxide film 31 (gate insulating film), a gate electrode 32, a drain electrode layer 40 (first electrode layer), a source electrode layer 50 (second electrode layer), and an interlayer insulating film 60.

MOSFET 101 is a power semiconductor device providing switching between drain electrode layer 40 and source electrode layer 50. Specifically, MOSFET 101 is preferably configured to be capable of applying a voltage of 600V or more, more preferably 1200V or more, and still more preferably 3300V or more, between drain electrode layer 40 and source electrode layer 50.

Epitaxial substrate 20 is made of a wide band gap semiconductor. The wide band gap semiconductor is preferably made of silicon carbide, gallium nitride or diamond. In the first embodiment, a wide band gap semiconductor material forming epitaxial substrate 20 is silicon carbide having a hexagonal crystal structure. Epitaxial substrate 20 has an upper surface P2, a lower surface P1, and a substrate side surface PS connecting lower surface P1 and upper surface P2. Epitaxial substrate 20 has a device region 20E, and a peripheral region 20T located on an outer side of device region 20E when viewed two-dimensionally.

In device region 20E, epitaxial substrate 20 includes a single-crystal substrate 29, a drift layer 21 having n type conductivity, a body region 22 having p type conductivity, a source region 23 having n type conductivity, and a contact region 24 having p type conductivity. Single-crystal substrate 29 has one surface forming lower surface P1. Drift layer 21 is provided on the surface of single-crystal substrate 29 that is opposite to lower surface P1. Body region 22 is in contact with drift layer 21. Body region 22 is separated from lower surface P1 by drift layer 21. The impurity concentration in body region 22 is preferably approximately 5×10¹⁷ cm⁻³ or more and approximately 3×10¹⁸ cm⁻³ or less, and is approximately 1×10¹⁸ cm⁻³, for example. Source region 23 is in contact with body region 22. Source region 23 partially forms upper surface P2. Contact region 24 is in contact with body region 22. Contact region 24 partially forms upper surface P2. Contact region 24 is higher in impurity concentration than body region 22.

Source electrode layer 50 is provided on upper surface P2 of epitaxial substrate 20 in the upper portion of device region 20E. Source electrode layer 50 has an ohmic portion 51 and a wiring portion 52. Ohmic portion 51 is in ohmic connection to upper surface P2 of epitaxial substrate 20. Specifically, ohmic portion 51 is in ohmic contact with source region 23 and contact region 24.

In device region 20E, trench TR is provided in upper surface P2 of epitaxial substrate 20. Trench TR has a sidewall surface SW and a bottom surface BT. Sidewall surface SW penetrates through source region 23 and body region 22 to drift layer 21. Thereby, body region 22 forms a portion corresponding to sidewall surface SW in upper surface P2. Sidewall surface SW includes a channel surface of MOSFET 101 on body region 22. Sidewall surface SW of trench TR may include a prescribed surface having a plane orientation of {0-33-8}, and preferably having a plane orientation of (0-33-8).

Gate oxide film 31 covers bottom surface BT and sidewall surface SW of trench TR. That is, gate oxide film 31 covers body region 22 on sidewall surface SW. Gate oxide film 31 may be formed in peripheral region 20T, and may cover a bottom surface 70a and a sidewall surface 70c of each of peripheral region trenches 70 to be described later. Gate electrode 32 is provided on gate oxide film 31.

In peripheral region 20T, epitaxial substrate 20 includes single-crystal substrate 29, drift layer 21 having n type conductivity, an electric field relaxing region 25, and a field stop region 28. Electric field relaxing region 25 has a JTE (Junction Termination Extension) region 26 and a guard ring region 27. Electric field relaxing region 25 and field stop region 28 include upper surface P2. A plurality of peripheral region trenches 70 are formed in electric field relaxing region 25. Specifically, the plurality of peripheral region trenches 70 are formed to surround the outer periphery of device region 20E, and preferably extend in a direction along the outer periphery of device region 20E. In a direction perpendicular to a direction in which each peripheral region trench 70 extends, constant spacing may be provided between peripheral region trenches 70.

Peripheral region trench 70 has bottom surface 70a and sidewall surface 70c in electric field relaxing region 25. Thereby, in electric field relaxing region 25, guard ring region 27 having a thick portion 27a defined by sidewall surface 70c of peripheral region trench 70, and a thin portion 27b defined by bottom surface 70a of peripheral region trench 70 is formed. In this embodiment, the impurity concentration in guard ring region 27 is equal to the impurity concentration in JTE region 26, and is approximately 5×10 ¹⁶ cm⁻³ or more and 1×10¹⁹ cm⁻³ or less, and preferably approximately 1×10¹⁷ cm⁻³ or more and 5×10¹⁸ cm⁻³ or less. The amount of impurity in guard ring region 27 is set to be lower than the amount of impurity in body region 22, and is preferably 10% or more and 40% or less of the amount of impurity in body region 22.

Sidewall surface 70c of peripheral region trench 70 may be formed perpendicular to upper surface P2, or may be an inclined surface having any angle. If sidewall surface 70c of peripheral region trench 70 is formed perpendicular or substantially perpendicular to upper surface P2, a creepage distance of upper surface P2 in peripheral region 20T can be effectively increased by peripheral region trench 70. If sidewall surface 70c of peripheral region trench 70 is formed such that it is inclined with respect to upper surface P2 to a degree similar to sidewall surface SW of trench TR, on the other hand, peripheral region trench 70 can be formed with the same method as that of trench TR, as will be described later, thereby suppressing the occurrence of a damaged layer in sidewall surface 70c due to processing.

A width of peripheral region trench 70 in the direction perpendicular to the direction in which peripheral region trench 70 extends (W1: FIG. 1) is narrower than a width in a direction perpendicular to a direction in which trench TR extends (W2: FIG. 1). In addition, a depth of peripheral region trench 70 in a direction perpendicular to upper surface P2 (D1: FIG. 1) is shallower than a depth of trench TR in the direction perpendicular to upper surface P2 (D2: FIG. 1). Widths W1 and depths D1 of peripheral region trenches 70 may be the same as or different from one another as long as they are set to be narrower and shallower than width W2 and depth D2 of trench TR, respectively. In addition, the spacings between peripheral region trenches 70 (C1: FIG. 1) may be the same as or different from one another, as long as they are 1 μm or more and 10 μm or less. Here, spacing C1 refers to the distance (pitch) between midpoints in a depth direction (the direction perpendicular to upper surface P2) of two sidewall surfaces 70c of peripheral region trenches 70 adjacent to each other with thick portion 27a interposed therebetween.

JTE region 26 has p type conductivity and is connected to body region 22. The impurity concentration in JTE region 26 is approximately 5×10¹⁶ cm⁻³ or more and 1×10¹⁹ cm⁻³ or less, and preferably approximately 1×10¹⁷ cm⁻³ or more and 5×10¹⁸ cm⁻³ or less. JTE region 26 may at least partially be covered with gate oxide film 31. In this case, JTE region 26 is formed to be located on an outer side of body region 22 in device region 20E.

Guard ring region 27 has p type conductivity and is connected to JTE region 26. That is, guard ring region 27 is connected to body region 22 with JTE region 26 interposed therebetween. Guard ring region 27 is formed close to the outer periphery of MOSFET 101 so as to surround JTE region 26.

Field stop region 28 has n type conductivity and is higher in impurity concentration than drift layer 21. Field stop region 28 is formed on upper surface P2 of epitaxial substrate 20, close to the outer periphery of MOSFET 101 so as to surround guard ring region 27

Drain electrode layer 40 is provided on lower surface P1 of epitaxial substrate 20. Drain electrode layer 40 is in ohmic connection to lower surface P1 of epitaxial substrate 20.

Interlayer insulating film 60 is provided on upper surface P2 of epitaxial substrate 20 and covers gate electrode 32. Gate oxide film 31 and interlayer insulating film 60 each have an opening through which each of source region 23 and contact region 24 is exposed at upper surface P2. In this opening, ohmic portion 51 of source electrode layer 50 is in ohmic contact with each of source region 23 and contact region 24.

A dielectric layer 61 is formed on upper surface P2 and covers peripheral region trench 70 in peripheral region 20T. In this case, dielectric layer 61 is formed to planarize peripheral region trench 70. Stated from a different viewpoint, dielectric layer 61 is formed with a small film thickness on thick portion 27a and with a great film thickness on thin portion 27b. Dielectric layer 61 may be formed as one piece with, or as a separate piece from interlayer insulating film 60. A material forming dielectric layer 61 may include at least one selected from the group consisting of, for example, silicon dioxide (SiO₂), polyimide, silicon nitride (SiN), and hafnium oxide (HfO₂) In this embodiment, dielectric layer 61 is formed as one piece with interlayer insulating film 60, and made of silicon dioxide.

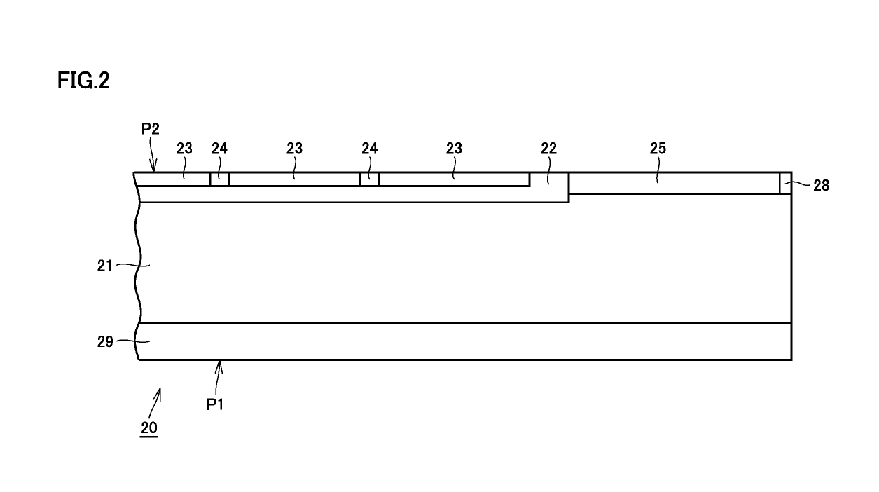

Referring now to FIGS. 2 to 7, a method of manufacturing the wide band gap semiconductor device according to the first embodiment is described.

Referring to FIG. 2, first, single-crystal substrate 29 having lower surface P1 is prepared. Then, drift layer 21 is formed by epitaxial growth on the surface opposite to lower surface P1. This epitaxial growth may be carried out with the CVD (Chemical Vapor Deposition) method. In this case, hydrogen gas may be used as carrier gas. Examples of source material gas may be mixed gas of silane (SiH₄ ) and propane (C₃H₈). In this case, it is preferred that nitrogen (N) or phosphorus (P) be introduced as impurities, for example.

Then, body region 22, source region 23, contact region 24, electric field relaxing region 25 and field stop region 28 are formed on drift layer 21, which may be implemented by ion implantation. Then, an activation annealing process for activating the impurities introduced by ion implantation is carried out. For example, heating is carried out for 30 minutes at a temperature of about 1700° C. in an atmosphere of argon (Ar) gas.

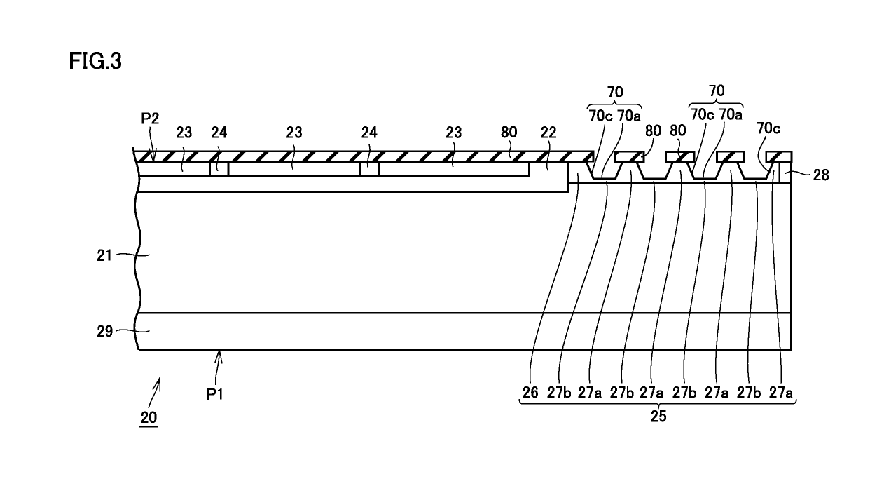

Then, referring to FIG. 3, a mask layer 80 having an opening is formed with the photolithography method, for example, on electric field relaxing region 25. Mask layer 80 can be made, for example, using silicon dioxide or a silicon oxide film.

Then, peripheral region trench 70 is formed in epitaxial substrate 20 by etching using mask layer 80, in which case thermal etching is preferred. Thermal etching may be carried out by heating in an atmosphere containing reaction gas having at least one or more types of halogen atoms, for example. The at least one or more types of halogen atoms each contain at least one of a chlorine (Cl) atom and a fluorine (F) atom. This atmosphere is Cl₂, BCl₃, SF₆, or CF₄, for example. Thermal etching is carried out using mixed gas of chlorine gas and oxygen gas as reaction gas, for example, at a heat treatment temperature of about 700° C. or higher and about 1000° C. or lower, for example. It is noted that the reaction gas may contain carrier gas in addition to the chlorine gas and oxygen gas described above. Examples of the carrier gas can be nitrogen (N₂) gas, argon gas, helium gas, and the like. Consequently, peripheral region trench 70 having sidewall surface 70c inclined with respect to upper surface P2 is formed in electric field relaxing region 25. As a result of the formation of peripheral region trench 70, JTE region 26 in contact with body region 22, and thick portion 27a and thin portion 27b connected to JTE region 26 are formed in electric field relaxing region 25.

In this case, peripheral region trench 70 is formed such that the amount of impurity in guard ring region 27 (the amount of impurity in thick portion 27a and thin portion 27b) is lower than the amount of impurity in body region 22. Preferably, peripheral region trench 70 is formed such that the amount of impurity in guard ring region 27 is 10% or more and 40% or less of the amount of impurity in body region 22. The amount of impurity in guard ring region 27 is determined by the amount of impurity in electric field relaxing region 25 and the dimensions of peripheral region trench 70 (such as width W1 and depth D: stated from a different viewpoint, the amount of etching of electric field relaxing region 25 in this step). That is, the amount of impurity in guard ring region 27 can be adjusted to a prescribed value by the amount of etching of electric field relaxing region 25. It is noted that width W1 and depth D1 of each peripheral region trench 70 formed such that the amount of impurity in guard ring region 27 is 10% or more and 40% or less of the amount of impurity in body region 22 can be set such that they are narrower and shallower than width W2 and depth D2 of trench TR, respectively.

Further, each peripheral region trench 70 is formed such that spacing C1 between peripheral region trenches 70 is 1 μm or more and 10 μm or less. Sidewall surface 70c of peripheral region trench 70 includes a prescribed surface having a plane orientation of {0-33-8}. After the formation of peripheral region trench 70, mask layer 80 is removed with any method such as etching.

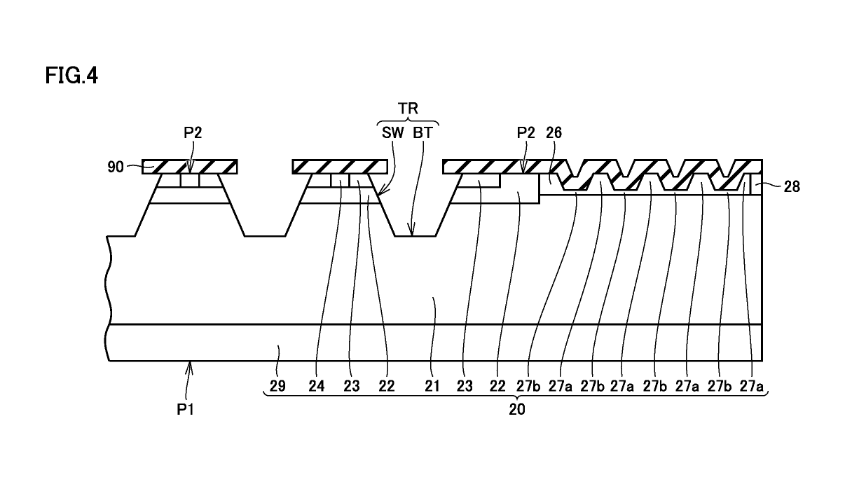

Then, referring to FIG. 4, a mask layer 90 having an opening is formed with the photolithography method, for example, on electric field relaxing region 25. Mask layer 90 can be made, for example, using silicon dioxide or a silicon oxide film.

Then, trench TR is formed in epitaxial substrate 20 by etching using mask layer 90, in which case thermal etching is preferred. Thermal etching may be carried out by heating in an atmosphere containing reaction gas having at least one or more types of halogen atoms, for example. The at least one or more types of halogen atoms each contain at least one of a chlorine (Cl) atom and a fluorine (F) atom. This atmosphere is Cl₂, BCl₃, SF₆, or CF₄, for example. Thermal etching is carried out using mixed gas of chlorine gas and oxygen gas as reaction gas, for example, at a heat treatment temperature of about 700° C. or higher and about 1000° C. or lower, for example. It is noted that the reaction gas may contain carrier gas in addition to the chlorine gas and oxygen gas described above. Examples of the carrier gas can be nitrogen (N₂) gas, argon gas, helium gas, and the like. Consequently, trench TR having sidewall surface SW inclined with respect to upper surface P2 is formed in epitaxial substrate 20. Sidewall surface SW of trench TR thus formed includes a prescribed surface having a plane orientation of {0-33-8}. After the formation of trench TR, mask layer 90 is removed with any method such as etching.

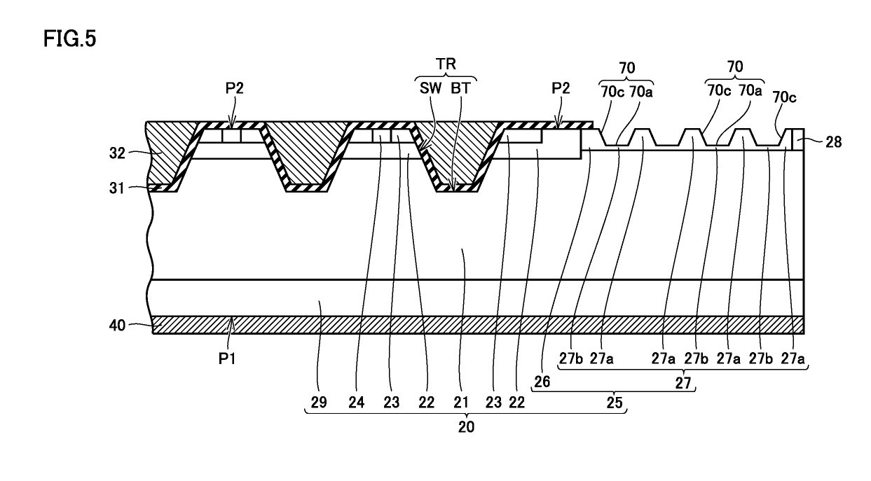

Then, referring to FIG. 5, gate oxide film 31 covering each of sidewall surface SW and bottom surface BT of trench TR is formed. Gate oxide film 31 may be formed by thermal oxidation of epitaxial substrate 20, for example. Gate oxide film 31 may be formed to a portion over at least a portion of JTE region 26, or may be formed to cover each of the sidewall surface and the bottom surface of peripheral region trench 70, for example, in peripheral region 20T.

Then, gate electrode 32 is formed on gate oxide film 31. Specifically, gate electrode 32 is formed to fill a region inside trench TR (region enclosed by sidewall surface SW and bottom surface BT) with gate oxide film 31 interposed therebetween. First, a conductor film to become gate electrode 32 is formed with the sputtering method or the like on gate oxide film 31. Examples of a material for the conductor film can be any material such as metal as long as it is a conductive material. Subsequently, a portion of the conductor film formed in a region other than the inside of trench TR is removed with any method such as etching back or the CMP method. The structure shown in FIG. 5 is thus obtained.

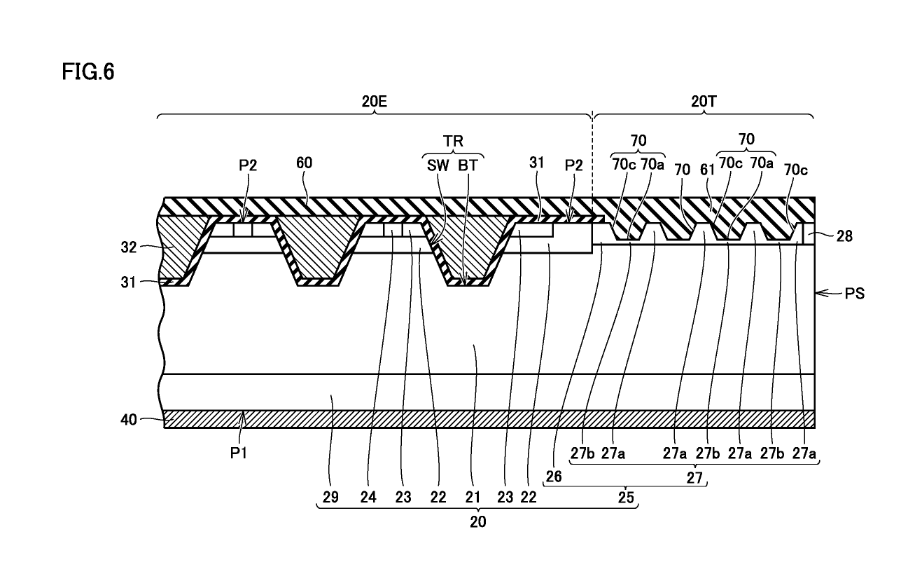

Then, referring to FIG. 6, interlayer insulating film 60 is formed on gate oxide film 31 and gate electrode 32, and dielectric layer 61 is formed on JTE region 26, guard ring region 27, and field stop region 28. Interlayer insulating film 60 and dielectric layer 61 may be formed as one piece or as separate pieces.

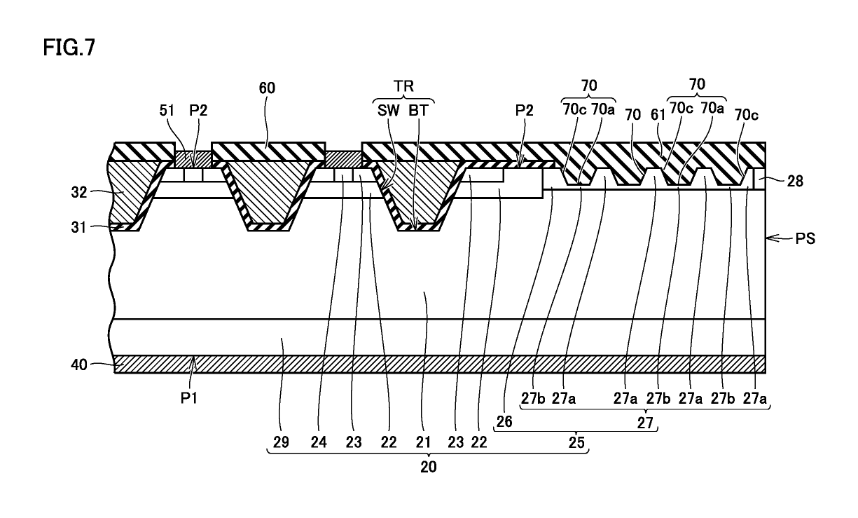

Then, referring to FIG. 7, source electrode layer 50 is formed. Specifically, first, etching is carried out such that an opening is formed in each of gate oxide film 31 and interlayer insulating film 60. This opening exposes each of source region 23 and contact region 24 at upper surface P2. Then, ohmic portion 51 in contact with each of source region 23 and n contact region 24 on upper surface P2 is formed. Then, wiring portion 52 is formed. MOSFET 101 is thus obtained.

Although peripheral region trench 70 is formed before the formation of trench TR in the method of manufacturing MOSFET 101 according to the first embodiment described above, peripheral region trench 70 may be formed after the formation of trench TR.

A function and effect of MOSFET 101 according to the first embodiment will now be described. In MOSFET 101 according to the first embodiment, since the plurality of peripheral region trenches 70 are formed, the creepage distance of upper surface P2 can be increased in the direction from device region 20E toward the outer peripheral end of the wide band gap semiconductor device. Further, electric field relaxing region 25 is provided without being divided by peripheral region trenches 70. Accordingly, a depletion layer readily expands at an interface between drift layer 21 and electric field relaxing region 25, particularly in a direction parallel to upper surface P2. As a result, electric field concentration can be effectively relaxed from device region 20E toward an outer peripheral end of peripheral region 20T, thereby improving the breakdown voltage of the wide band gap semiconductor device.

Further, since electric field relaxing region 25 is provided without being divided by peripheral region trenches 70, the entire electric field relaxing region 25 can have the same potential. Consequently, the entire electric field relaxing region 25 (JTE region 26 and guard ring region 27 in FIG. 1) can be source-grounded by connecting electric field relaxing region 25 to source region 23 on the side close to device region 20E, for example. As a result, when a voltage is applied between the source and drain resulting in depletion of the interface between drift layer 21 and electric field relaxing region 25, and then the application of the voltage is suspended, for example, conductive ions (carriers) in electric field relaxing region 25 can be quickly recovered. Thus, ON operation of the wide band gap semiconductor device can be effected in a state where the conductive ions in electric field relaxing region 25 have been reliably recovered, thereby suppressing characteristic variation during the ON operation.

Further, in this embodiment, the amount of impurity in guard ring region 27 is set to be lower than the amount of impurity in body region 22, and is preferably set to 10% or more and 40% or less of the amount of impurity in body region 22. When the amount of impurity in guard ring region 27 is as high as the amount of impurity in an active region (body region 22), it is difficult to relax electric field concentration at the outer peripheral end of peripheral region 20T. In MOSFET 101 according to this embodiment, the amount of impurity in guard ring region 27 can be set to 10% or more and 40% or less of the amount of impurity in body region 22 by forming peripheral region trench 70, thereby more effectively relaxing electric field concentration at the outer peripheral end of peripheral region 20T. That is, a depletion layer can be sufficiently expanded from electric field relaxing region 25 to drift layer 21 throughout peripheral region 20T, thereby effectively relaxing electric field concentration at the outer peripheral end of peripheral region 20T throughout peripheral region 20T.

Moreover, since spacing C1 between peripheral region trenches 70 is 1 μm or more and 10 μm or less, depletion layers formed at an interface between drift layer 21 and JTE region 26, thick portion 27a or thin portion 27b can sufficiently overlap with each other. As a result, electric field concentration at the outer peripheral end of peripheral region 20T can be effectively relaxed throughout peripheral region 20T.

### Second Embodiment

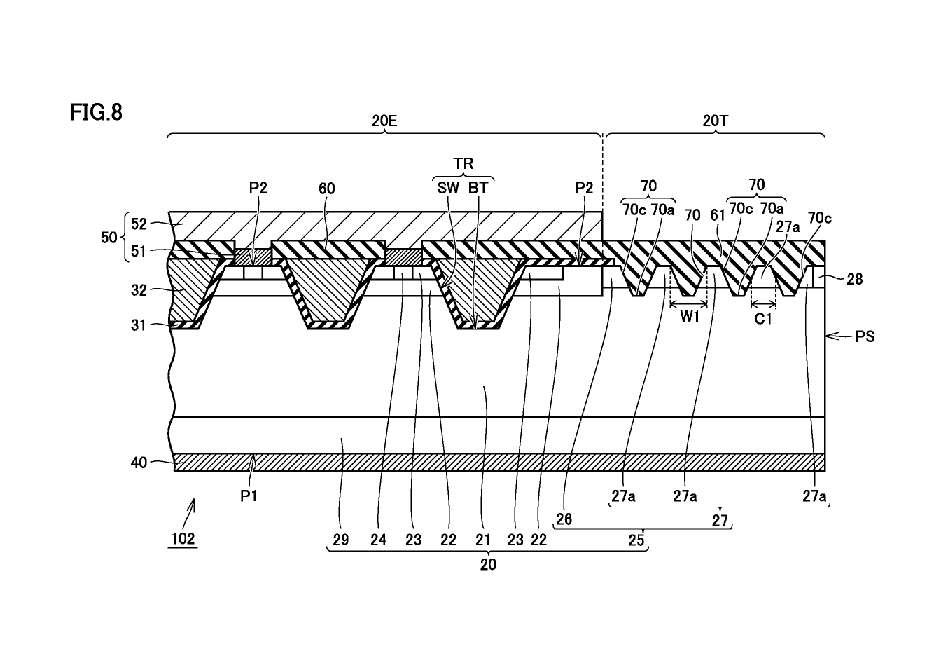

Referring now to FIG. 8, a wide band gap semiconductor device according to a second embodiment is described. The wide band gap semiconductor device (MOSFET 102) according to the second embodiment basically has the same configuration as that of the wide band gap semiconductor device according to the first embodiment, but is different in that sidewall surface 70c of peripheral region trench 70 extends from electric field relaxing region 25 to drift layer 21. In this case, bottom surface 70a of peripheral region trench 70 is formed in drift layer 21. That is, thin portions 27b are not formed in the wide band gap semiconductor device according to the second embodiment. In this case, thick portions 27a of guard ring region 27 have a so-called floating guard ring structure in which the plurality of thick portions 27a are formed by being defined by sidewall surfaces 70c of peripheral region trenches 70 but they are not connected together.

Again in this case, since the plurality of peripheral region trenches 70 are formed, the creepage distance of upper surface P2 can be increased in the direction from device region 20E toward the outer peripheral end of the wide band gap semiconductor device, without an increase in spatial distance of peripheral region 20T (the shortest straight-line distance from device region 20E to the outer peripheral end of the wide band gap semiconductor device). As a result, the wide band gap semiconductor device according to the second embodiment can achieve a higher breakdown voltage without an increase in size, as with the wide band gap semiconductor device according to the first embodiment.

Moreover, since spacing Cl between peripheral region trenches 70 is 1 μm or more and 10 μm or less, depletion layers formed at the interface between drift layer 21 and JTE region 26, guard ring region 27 (thick portion 27a) can sufficiently overlap with each other. As a result, electric field concentration at the outer peripheral end of peripheral region 20T can be effectively relaxed throughout peripheral region 20T.

### FIRST REFERENCE EXAMPLE

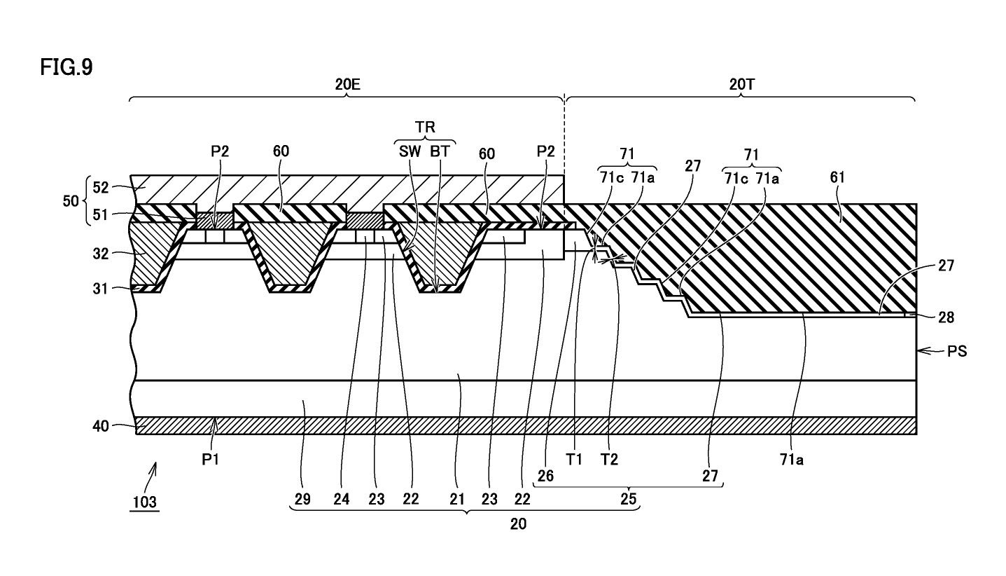

Referring now to FIG. 9, a wide band gap semiconductor device according to a first reference example is described. A MOSFET 103 as an example of the wide band gap semiconductor device according to the first reference example is a trench gate type transistor. MOSFET 103 includes epitaxial substrate 20 (semiconductor substrate), gate oxide film 31 (gate insulating film), gate electrode 32, drain electrode layer 40 (first electrode layer), source electrode layer 50 (second electrode layer), and interlayer insulating film 60.

MOSFET 103 is a power semiconductor device providing switching between drain electrode layer 40 and source electrode layer 50. Specifically, MOSFET 103 is preferably configured to be capable of applying a voltage of 600V or more, more preferably 1200V or more, and still more preferably 3300V or more, between drain electrode layer 40 and source electrode layer 50.

Epitaxial substrate 20 is made of a wide band gap semiconductor. The wide band gap semiconductor is preferably made of silicon carbide, gallium nitride or diamond. In the first reference example, a wide band gap semiconductor material forming epitaxial substrate 20 is silicon carbide having a hexagonal crystal structure. Epitaxial substrate 20 has upper surface P2, lower surface P1, and substrate side surface PS connecting lower surface P1 and upper surface P2. Epitaxial substrate 20 has device region 20E, and peripheral region 20T located on an outer side of device region 20E when viewed two-dimensionally.

In device region 20E, epitaxial substrate 20 includes single-crystal substrate 29, drift layer 21 having n type conductivity, body region 22 having p type conductivity, source region 23 having n type conductivity, and contact region 24 having p type conductivity. Single-crystal substrate 29 has one surface forming lower surface P1. Drift layer 21 is provided on the surface of single-crystal substrate 29 that is opposite to lower surface P1. Body region 22 is in contact with drift layer 21. Body region 22 is separated from lower surface P1 by drift layer 21. The impurity concentration in body region 22 is preferably approximately 5×10¹⁷ cm⁻³ or more and approximately 3×10¹⁸ cm⁻³ or less, and is approximately 1×10¹⁸ cm⁻³, for example. Source region 23 is in contact with body region 22. Source region 23 partially forms upper surface P2. Contact region 24 is in contact with body region 22. Contact region 24 partially forms upper surface P2. Contact region 24 is higher in impurity concentration than body region 22.

Source electrode layer 50 is provided on upper surface P2 of epitaxial substrate 20 in the upper portion of device region 20E. Source electrode layer 50 has ohmic portion 51 and wiring portion 52. Ohmic portion 51 is in ohmic connection to upper surface P2 of epitaxial substrate 20. Specifically, ohmic portion 51 is in ohmic connection to source region 23 and contact region 24.

In device region 20E, trench TR is provided in upper surface P2 of epitaxial substrate 20 Trench TR has sidewall surface SW and bottom surface BT. Sidewall surface SW penetrates through source region 23 and body region 22 to drift layer 21. Thereby, body region 22 forms a portion corresponding to sidewall surface SW in upper surface P2. Sidewall surface SW includes a channel surface of MOSFET 101 on body region 22. Sidewall surface SW of trench TR may include a prescribed surface having a plane orientation of {0-33-8}, and preferably having a plane orientation of (0-33-8).

Gate oxide film 31 covers sidewall surface SW and bottom surface BT of trench TR. That is, gate oxide film 31 covers body region 22 on sidewall surface SW. Gate oxide film 31 may be formed in peripheral region 20T, and may cover a terrace surface 71a and a step surface 71c of each of stepped portions 71 to be described later. Gate electrode 32 is provided on gate oxide film 31.

In peripheral region 20T, epitaxial substrate 20 includes single-crystal substrate 29, drift layer 21 having n type conductivity, electric field relaxing region 25, and field stop region 28. Electric field relaxing region 25 has JTE (Junction Termination Extension) region 26 and guard ring region 27. Epitaxial substrate 20 has a plurality of stepped portions 71 in peripheral region 20T. The plurality of stepped portions 71 each have step surface 71c inclined with respect to upper surface P2, and bottom surface 70a intersecting with step surface 71c. Step surface 71c of stepped portion 71 and sidewall surface SW of trench TR may be provided parallel to each other. Stepped portions 71 are formed to annularly surround the outer periphery of device region 20E, and preferably extend in the direction along the outer periphery of device region 20E. Electric field relaxing region 25 and field stop region 28 include upper surface P2, and are formed along the plurality of stepped portions 71.

JTE region 26 has p type conductivity and is connected to body region 22. The impurity concentration in JTE region 26 is approximately 5×10¹⁶ cm⁻³ or more and 1×10¹⁹ cm⁻³ or less, and preferably approximately 1×10¹⁷ cm⁻³ or more and 5×10¹⁸ cm⁻³ or less. JTE region 26 may at least partially be covered with gate oxide film 31. In this case, JTE region 26 is formed to be located on an outer side of body region 22 in device region 20E, and includes upper surface P2.

Guard ring region 27 has p type conductivity and is connected to JTE region 26. That is, guard ring region 27 is connected to body region 22 with JTE region 26 interposed therebetween. As described above, guard ring region 27 is formed along the plurality of stepped portions 71 formed in drift layer 21, and to include upper surface P2. That is, guard ring region 27 is formed in peripheral region 20T to include upper surface P2 from a position which is connected to JTE region 26 and includes upper surface P2 to a position which is in contact with field stop region 28 and farthest from a surface of dielectric layer 61 (position closest to lower surface P1). In this embodiment, the impurity concentration in guard ring region 27 is equal to the impurity concentration in JTE region 26, and is approximately 5×10¹⁶ cm⁻³ or more and 1×10¹⁹ cm⁻³ or less, and preferably approximately 1×10¹⁷ cm⁻³ or more and 5×10¹⁸ cm⁻³ or less. A thickness T1 of guard ring region 27 formed on terrace surface 71a of stepped portion 71 is set to be greater than a thickness T2 of guard ring region 27 formed on step surface 71c of stepped portion 71.

Step surface 71c of stepped portion 71 may be an inclined surface having any angle with respect to upper surface P2, or may be formed perpendicular to upper surface P2. Preferably, step surface 71c is a surface that self-forms by thermal etching or the like. In this case, stepped portion 71 can be formed with the same method as that of trench TR, as will be described later, thereby suppressing the occurrence of a damaged layer in step surface 71c due to processing.

Field stop region 28 has n type conductivity and is higher in impurity concentration than drift layer 21. Field stop region 28 is formed on upper surface P2 of epitaxial substrate 20, close to the outer periphery of MOSFET 101 so as to surround guard ring region 27. That is, field stop region 28 is formed in peripheral region 20T in a position farthest from the surface of dielectric layer 61, so as to include upper surface P2.

Drain electrode layer 40 is provided on lower surface P1 of epitaxial substrate 20. Drain electrode layer 40 is in ohmic connection to lower surface P1 of epitaxial substrate 20

Interlayer insulating film 60 is provided on upper surface P2 of epitaxial substrate 20 and covers gate electrode 32. Gate oxide film 31 and interlayer insulating film 60 each have an opening through which each of source region 23 and contact region 24 is exposed at upper surface P2. In this opening, ohmic portion 51 of source electrode layer 50 is in ohmic contact with each of source region 23 and contact region 24.

Dielectric layer 61 is formed on upper surface P2 to fill stepped portion 71 in peripheral region 20T. That is, peripheral region 20T is planarized by dielectric layer 61. Stated from a different viewpoint, dielectric layer 61 is formed such that its thickness is greater on the side close to the outer periphery than on the side close to device region 20E in peripheral region 20T. Dielectric layer 61 may be formed as one piece with, or as a separate piece from interlayer insulating film 60. A material forming dielectric layer 61 may include at least one selected from the group consisting of, for example, silicon dioxide (SiO₂), polyimide, silicon nitride (SiN), and hafnium oxide (HfO₂). In this embodiment, dielectric layer 61 is formed as one piece with interlayer insulating film 60, and made of silicon dioxide.

Referring now to FIGS. 9 to 15, a method of manufacturing the wide band gap semiconductor device according to the first reference example is described.

First, single-crystal substrate 29 having lower surface P1 is prepared. Then, drift layer 21 is formed by epitaxial growth on the surface opposite to lower surface P1. This epitaxial growth may be carried out with the CVD (Chemical Vapor Deposition) method. In this case, hydrogen gas may be used as carrier gas. Examples of source material gas may be mixed gas of silane (SiH₄) and propane (C₃H₈). In this case, it is preferred that nitrogen (N) or phosphorus (P) be introduced as impurities, for example.

Then, body region 22, source region 23, contact region 24, and electric field relaxing region 25 are formed on drift layer 21, which may be implemented by ion implantation. Then, an activation annealing process for activating the impurities introduced by ion implantation is carried out. For example, heating is carried out for 30 minutes at a temperature of about 1700° C. in an atmosphere of argon (Ar) gas.

Then, mask layer 90 having an opening is formed with the photolithography method, for example, on electric field relaxing region 25. Mask layer 90 can be made, for example, using silicon dioxide or a silicon oxide film.

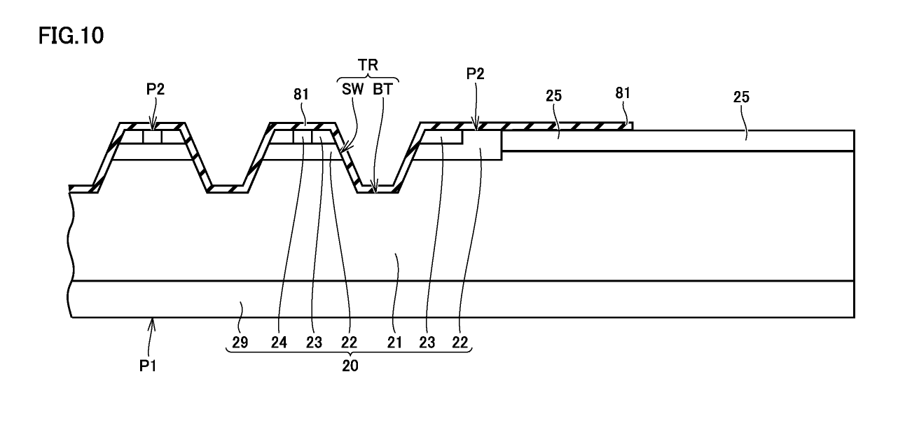

Then, trench TR is formed in epitaxial substrate 20 by etching using mask layer 90, in which case thermal etching is preferred. Thermal etching may be carried out by heating in an atmosphere containing reaction gas having at least one or more types of halogen atoms, for example. The at least one or more types of halogen atoms each contain at least one of a chlorine (Cl) atom and a fluorine (F) atom. This atmosphere is Cl₂, BCl₃, SF₆, or CF₄, for example. Thermal etching is carried out using mixed gas of chlorine gas and oxygen gas as reaction gas, for example, at a heat treatment temperature of about 700° C. or higher and about 1000° C. or lower, for example. It is noted that the reaction gas may contain carrier gas in addition to the chlorine gas and oxygen gas described above. Examples of the carrier gas can be nitrogen (N₂) gas, argon gas, helium gas, and the like. Consequently, trench TR having sidewall surface SW inclined with respect to upper surface P2 is formed in epitaxial substrate 20. Sidewall surface SW of trench TR thus formed includes a prescribed surface having a plane orientation of {0-33-8}. After the formation of trench TR, mask layer 90 is removed with any method such as etching. The structure shown in FIG. 10 is thus obtained.

Then, the plurality of stepped portions 71 are formed. Specifically, first, a mask layer 81 having an opening is formed with the photolithography method, for example, on electric field relaxing region 25. Mask layer 81 can be made, for example, using silicon dioxide or a silicon oxide film.

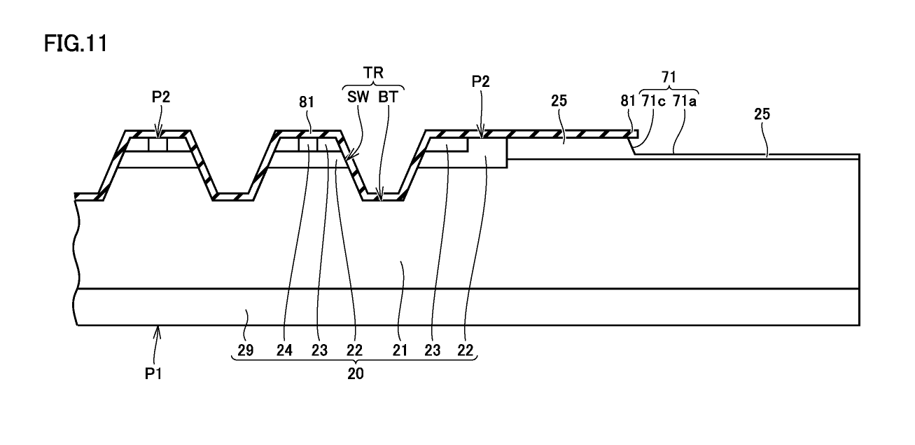

Then, one stepped portion 71 is formed in epitaxial substrate 20 by etching using mask layer 81, in which case thermal etching is preferred. Thermal etching may be carried out by heating in an atmosphere containing reaction gas having at least one or more types of halogen atoms, for example. The at least one or more types of halogen atoms each contain at least one of a chlorine (Cl) atom and a fluorine (F) atom. This atmosphere is Cl₂, BCl₃, SF₆, or CF₄, for example. Thermal etching is carried out using mixed gas of chlorine gas and oxygen gas as reaction gas, for example, at a heat treatment temperature of about 700° C. or higher and about 1000° C. or lower, for example. It is noted that the reaction gas may contain carrier gas in addition to the chlorine gas and oxygen gas described above. Examples of the carrier gas can be nitrogen (N₂) gas, argon gas, helium gas, and the like. Consequently, referring to FIG. 11, one stepped portion 71 having step surface 71c inclined with respect to upper surface P2 is formed in electric field relaxing region 25. In this case, step surface 71c of stepped portion 71 includes a prescribed surface having a plane orientation of {0-33-8}.

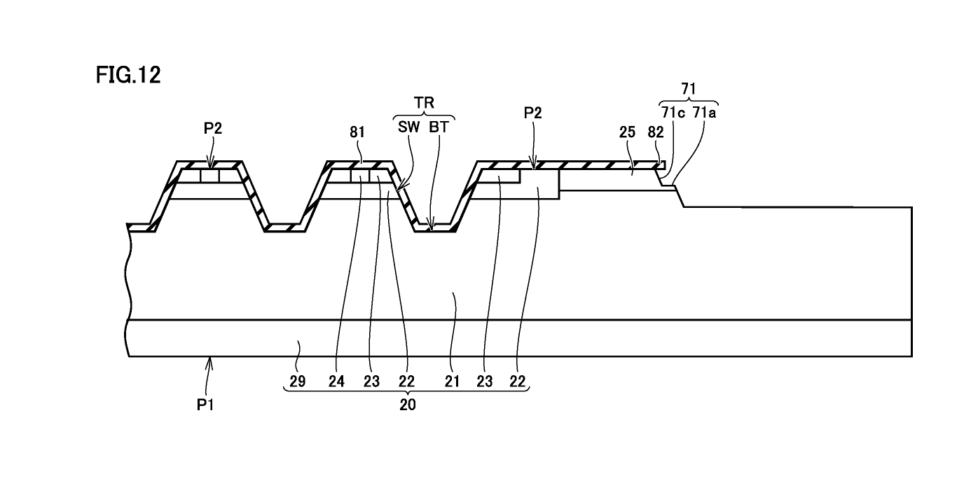

Then, a mask layer 82 having an opening is formed on electric field relaxing region 25. Mask layer 82 is formed by processing mask layer 81, or newly formed with the photolithography method. In this case, it is preferred that mask layer 82 be formed to have an opening larger than the opening of mask layer 81 on the side close to device region 20E. In this manner, referring to FIG. 12, two stepped portions 71 are formed in peripheral region 20T. A prescribed number of stepped portions 71 can be formed by repeating the same steps.

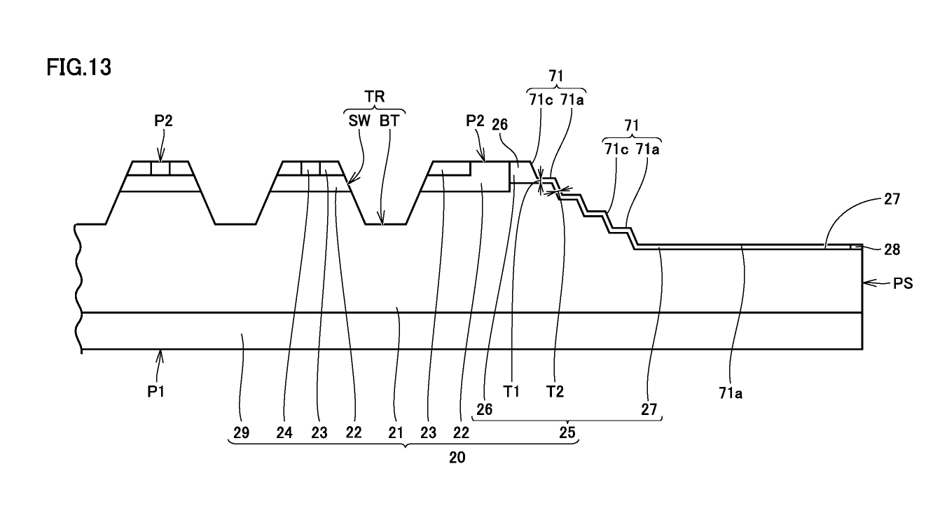

Then, referring to FIG. 13, guard ring region 27 and the field stop portion are formed on the plurality of stepped portions 71 formed in peripheral region 20T, which may be implemented by ion implantation after device region 20E is covered with an ion implantation mask (not shown). Then, an activation annealing process for activating the impurities introduced by ion implantation is carried out. For example, heating is carried out for 30 minutes at a temperature of about 1700° C. in an atmosphere of argon (Ar) gas. The structure shown in FIG. 13 is thus obtained.

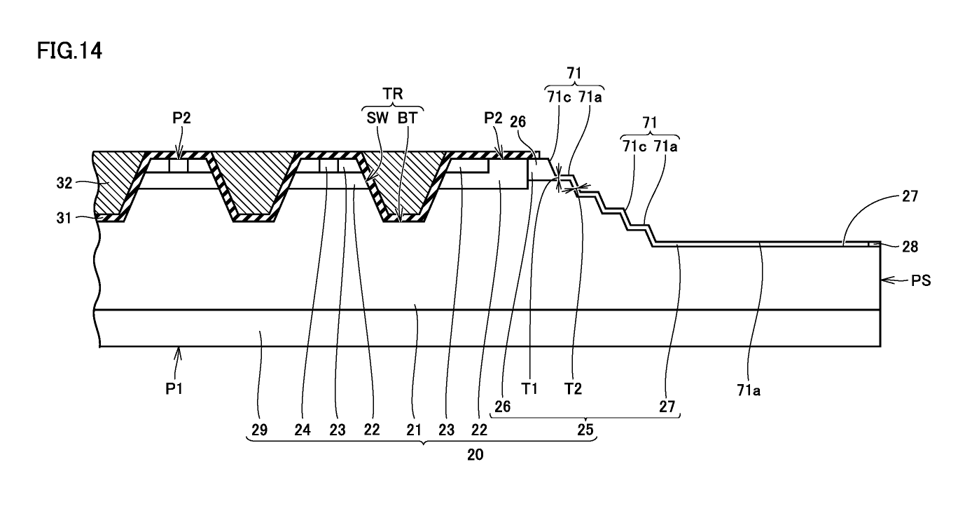

Then, referring to FIG. 14, gate oxide film 31 covering each of sidewall surface SW and bottom surface BT of trench TR is formed. Gate oxide film 31 may be formed by thermal oxidation of epitaxial substrate 20, for example. Gate oxide film 31 may be formed to a portion over at least a portion of JTE region 26, or may be formed to cover each of terrace surface 71a and step surface 71c of the plurality of stepped portions 71, for example, in peripheral region 20T.

Then, gate electrode 32 is formed on gate oxide film 31. Specifically, gate electrode 32 is formed to fill a region inside trench TR (region enclosed by sidewall surface SW and bottom surface BT) with gate oxide film 31 interposed therebetween. First, a conductor film to become gate electrode 32 is formed with the sputtering method or the like on gate oxide film 31. Examples of a material for the conductor film can be any material such as metal as long as it is a conductive material. Subsequently, a portion of the conductor film formed in a region other than the inside of trench TR is removed with any method such as etching back or the CMP method. The structure shown in FIG. 14 is thus obtained.

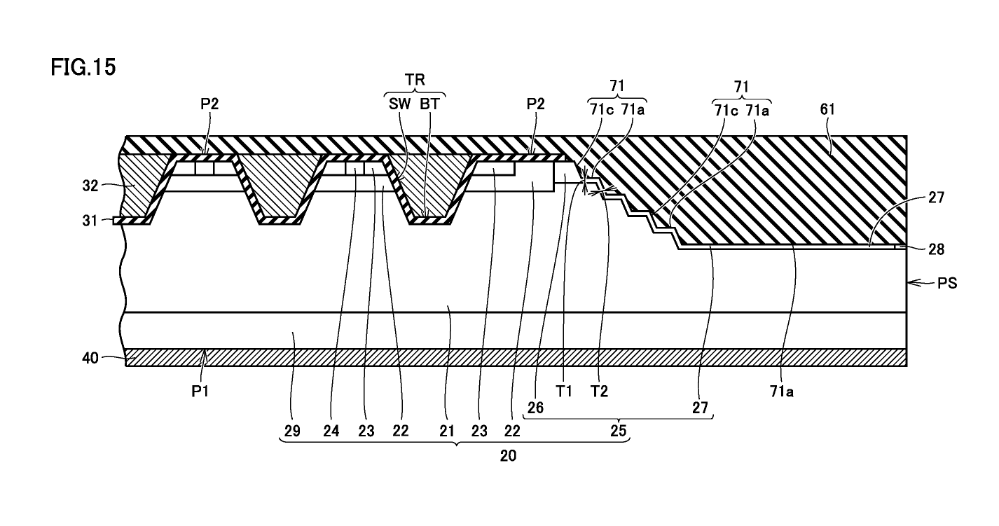

Then, referring to FIG. 15, interlayer insulating film 60 is formed on gate oxide film 31 and gate electrode 32, and dielectric layer 61 is formed on JTE region 26, guard ring region 27, and field stop region 28. Interlayer insulating film 60 and dielectric layer 61 may be formed as one piece or as separate pieces.

Then, source electrode layer 50 is formed. Specifically, first, etching is carried out such that an opening is formed in each of gate oxide film 31 and interlayer insulating film 60. This opening exposes each of source region 23 and contact region 24 at upper surface P2. Then, ohmic portion 51 in contact with each of source region 23 and n contact region 24 on upper surface P2 is formed. Then, wiring portion 52 is formed. MOSFET 103 shown in FIG. 9 is thus obtained.

Although stepped portion 71 is formed after the formation of trench TR in the method of manufacturing MOSFET 103 according to the first reference example described above, stepped portion 71 may be formed before the formation of trench TR.

A function and effect of MOSFET 103 according to the first reference example will now be described. In MOSFET 103 according to the first reference example, since the plurality of stepped portions 71 annularly surrounding device region 20E are formed in peripheral region 20T, the creepage distance of upper surface P2 can be increased in the direction from device region 20E toward the outer peripheral end of the wide band gap semiconductor device. That is, the creepage distance of main surface P2 in peripheral region 20T can be increased without an increase in spatial distance of peripheral region 20T (the shortest straight-line distance from device region 20E to the outer peripheral end of the wide band gap semiconductor device). As a result, MOSFET 103 according to the first reference example can achieve a higher breakdown voltage without an increase in size.

Further, in MOSFET 103 according to the first reference example, thickness T1 of electric field relaxing region 25 on terrace surface 71a is greater than thickness T2 of electric field relaxing region 25 on step surface 71c. Accordingly, at an interface between drift layer 21 and electric field relaxing region 25, a depletion layer can be readily expanded in the direction perpendicular to upper surface P2. Thus, depletion layers formed at the interface between drift layer 21 and electric field relaxing region 25 formed along the plurality of stepped portions 71 on drift layer 21 can be connected together in the direction parallel to upper surface P2 as well, allowing for the formation of a large depletion layer in peripheral region 20T in both directions parallel to and perpendicular to upper surface P2. As a result, MOSFET 103 according to the first reference example can achieve a further improved breakdown voltage.

Further, dielectric layer 61 is formed on stepped portions 71, and electric field relaxing region 25 is formed to be sandwiched between drift layer 21 and dielectric layer 61 in stepped portions 71. Accordingly, dielectric layer 61 can protect electric field relaxing region 25, and more effectively relax electric field concentration in semiconductor substrate 20 and at an interface (upper surface P2) between semiconductor substrate 20 and dielectric layer 61 in peripheral region 20T

Further, in MOSFET 103 according to the first reference example, the plurality of stepped portions 71 are formed in a step-like manner toward lower surface P1 as the distance to the outer periphery decreases. That is, an end portion of electric field relaxing region 25 that is located close to the outer periphery of the wide band gap semiconductor device (portion in contact with field stop region 28) is formed in a position closer to lower surface P1 than any other portion of electric field relaxing region 25. In this case, since dielectric layer 61 is formed to fill stepped portions 71, dielectric layer 61 is formed such that its thickness increases from a portion over the end portion of electric field relaxing region 25 that is located close to device region 20E (JTE region 26) toward a portion over the outermost peripheral end of electric field relaxing region 25. Thus, MOSFET 103 according to the first reference example can relax electric field concentration close to the outer periphery of peripheral region 20T where electric field concentration tends to occur upon application of a high voltage in a common semiconductor device having a guard ring structure, and can lower the potential of the surface of dielectric layer 61 located close to the outer periphery of peripheral region 20T. As a result, MOSFET 103 according to the first reference example can lower the risk of occurrence of discharge on dielectric layer 61.

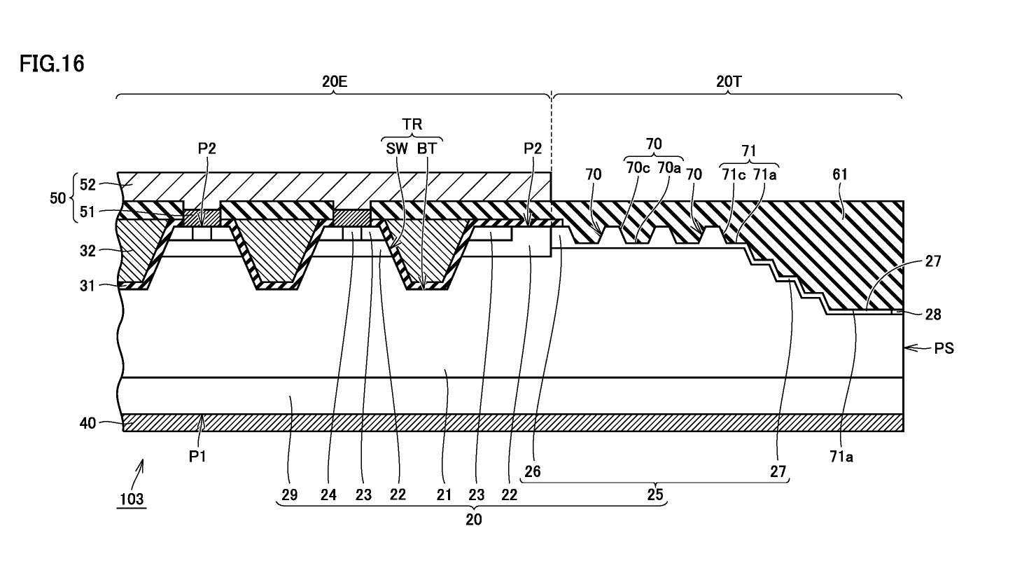

In addition, referring to FIG. 16, MOSFETs 101, 102 according to the first or second embodiment may further include stepped portions 71 described in the first reference example in electric field relaxing region 25. In this case, it is preferred that the plurality of stepped portions 71 be formed closer to the outer periphery than peripheral region trenches 70 formed in electric field relaxing region 25. Although peripheral region trenches 70 are formed in electric field relaxing region 25 in the example shown in FIG. 16, sidewall surface 70c of each peripheral region trench 70 may extend from electric field relaxing region 25 to drift layer 21, with bottom surface 70a formed in drift layer 21. Consequently, the same effects as those of MOSFETs 101, 102 according to the first or second embodiment described above can be further achieved.

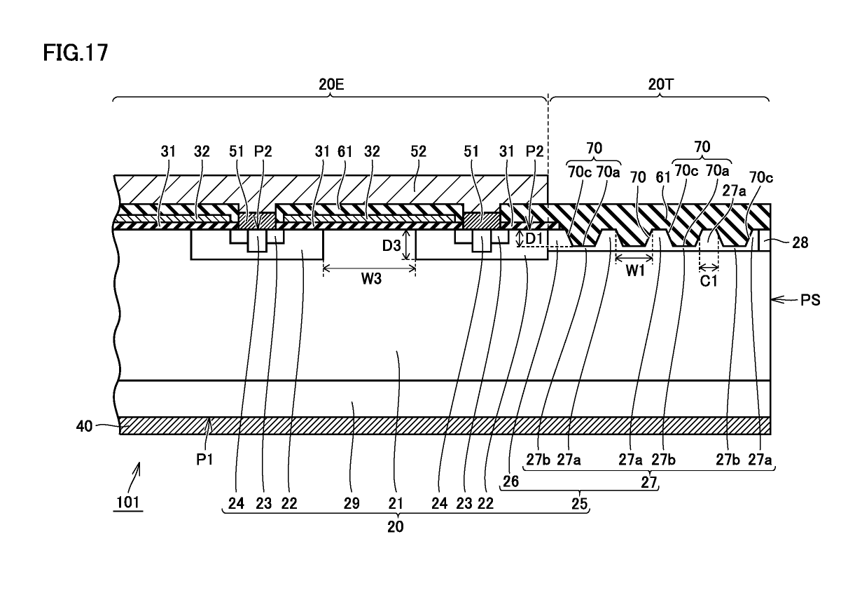

Although each of MOSFETs 101, 102 according to the first, second embodiments and MOSFET 103 according to the first reference example is formed as a trench gate type, it may be formed as a planar type. FIG. 17 is a cross-sectional view of planar type MOSFET 101 as a variation of the wide band gap semiconductor device according to the first embodiment. When each of the wide band gap semiconductor devices according to the first and second embodiments is formed as planar type MOSFET 101, width WI of peripheral region trench 70 in the direction perpendicular to the direction in which peripheral region trench 70 extends is preferably set to be narrower than spacing W3 between body regions 22 facing each other with the JFET region (region located between body regions 22 in drift layer 21) interposed therebetween. In addition, depth D1 of peripheral region trench 70 in the direction perpendicular to upper surface P2 is preferably set to be shallower than depth D3 of the bottom of each body region 22 from upper surface P2. In this case, since the width of peripheral region trench 70 is sufficiently narrow, spacing between depletion layers expanding from electric field relaxing regions 25 facing each other with peripheral region trench 70 interposed therebetween toward drift layer 21 can be reduced in the direction perpendicular to the direction in which peripheral region trench 70 extends, or the depletion layers can be readily expanded such that they are connected together while extending over peripheral region trench 70. As a result, electric field concentration in the vicinity of device region 20E and in peripheral region 20T can be relaxed to improve the breakdown voltage of the wide band gap semiconductor device.

Although electric field relaxing region 25 is formed by ion implantation in the methods of manufacturing the wide band gap semiconductor devices according to the first and second embodiments as well as the first reference example, this is not restrictive. For example, electric field relaxing region 25 may be formed by epitaxial growth.

In addition, in the methods of manufacturing the wide band gap semiconductor devices according to the first and second embodiments as well as the first reference example, the order of the steps of forming peripheral region trench 70 and stepped portion 71 in peripheral region 20T and each step of forming the device structure in device region 20E is not limited to the order described above, but may be selected as appropriate.

Although the embodiments of the present invention have been described above, the embodiments described above can be modified in various ways. Further, the scope of the present invention is not limited to the embodiments described above. The scope of the present invention is defined by the terms of the claims, and is intended to include any modifications within the scope and meaning equivalent to the terms of the claims.

[Aspects]

The wide band gap semiconductor devices according to the first and second embodiments described above can also be applied to a semiconductor device made of any semiconductor material.

(2-1) A semiconductor device according to this embodiment includes a semiconductor substrate (epitaxial substrate 20) having a main surface (upper surface P2), semiconductor substrate 20 including a device region 20E formed in semiconductor substrate 20, and a peripheral region 20T formed to surround device region 20E. In peripheral region 20T, semiconductor substrate 20 includes a first semiconductor region (drift layer 21) having a first conductivity type, and a second semiconductor region (electric field relaxing region 25) formed on the first semiconductor region (drift layer 21) and having main surface P2, the second semiconductor region having a second conductivity type different from the first conductivity type, and a plurality of peripheral region trenches 70 annularly surrounding device region 20E are formed in main surface P2 of the second semiconductor region (electric field relaxing region 25). Semiconductor substrate 20 may be made of silicon (Si) or a wide band gap semiconductor, for example.

(2-2) In the semiconductor device according to this embodiment, peripheral region trenches 70 may be formed in the second semiconductor region (electric field relaxing region 25).

(2-3) In the semiconductor device according to this embodiment, a sidewall of each of peripheral region trenches 70 may extend from the second semiconductor region (electric field relaxing region 25) to the first semiconductor region (drift layer 21).

(2-4) A dielectric layer covering peripheral region trenches 70 may be formed on the main surface (upper surface P2) of the second semiconductor region.

(2-5) A material forming the dielectric layer may include at least one selected from the group consisting of silicon dioxide, polyimide, and silicon nitride.

(2-6) In the device region of the semiconductor device according to this embodiment, a device trench TR may be provided in the main surface (P2) of the semiconductor substrate (epitaxial substrate 20), a width of each of peripheral region trenches 70 at the main surface (P2) in a direction perpendicular to a direction in which peripheral region trench 70 extends may be smaller than a width of device trench TR at the main surface (P2) in a direction perpendicular to a direction in which device trench TR extends, and a depth of each of peripheral region trenches 70 in a direction perpendicular to the main surface (upper surface P2) may be smaller than a depth of device trench TR in the direction perpendicular to the main surface (upper surface P2).

(2-7) In the device region, the semiconductor substrate (epitaxial substrate 20) may include the first semiconductor region (drift layer 21) having the main surface (upper surface P2), a pair of third semiconductor regions (body regions 22) spaced apart from and facing each other at main surface P2, the third semiconductor regions having the second conductivity type, and a fourth semiconductor region having the first conductivity type in each of the pair of third semiconductor regions (body regions 22), a width of each of peripheral region trenches 70 at the main surface (P2) in a direction perpendicular to a direction in which peripheral region trench 70 extends may be smaller than spacing between the third semiconductor regions (p body regions 22) facing each other with the first semiconductor region interposed therebetween at main surface P2, and a depth of each of peripheral region trenches 70 in a direction perpendicular to the main surface may be smaller than a depth of a bottom of each of the third semiconductor regions (p body regions 22) from the main surface.

(2-8) A sidewall of each of peripheral region trenches 70 may be inclined with respect to main surface P2.

(2-9) The first conductivity type may be n type, and the second conductivity type may be p type.

### INDUSTRIAL APPLICABILITY

The present invention is applied particularly advantageously to a semiconductor device required to have a high breakdown voltage.

### REFERENCE SIGNS LIST

20 semiconductor substrate; 20E device region; 20T peripheral region; 21 drift layer (first semiconductor region); 22 body region (third semiconductor region); 23 source region (fourth semiconductor region); 24 contact region; 25 electric field relaxing region (second semiconductor region); 27 guard ring region; 27a thick portion; 27b thin portion; 28 field stop region; 29 single-crystal substrate; 31 gate oxide film; 32 gate electrode; 40 drain electrode layer; 50 source electrode layer; 51 ohmic portion; 52 wiring portion; 60 interlayer insulating film; 61 dielectric layer; 70 peripheral region trench; 70a bottom surface; 70c sidewall surface; 71 stepped portion; 71a terrace surface; 71c step surface; 80, 81, 82, 90 mask layer; 101, 102, 103 MOSFET; TR trench; BT bottom surface; SW sidewall surface; P1 lower surface; P2 upper surface (main surface); PS substrate side surface.

1. A wide band gap semiconductor device, comprising a semiconductor substrate having a main surface and made of a wide band gap semiconductor,
the semiconductor substrate including a device region formed in the semiconductor substrate, and a peripheral region formed to surround the device region,
in the peripheral region,
the semiconductor substrate including a first semiconductor region having a first conductivity type, and a second semiconductor region formed on the first semiconductor region and having the main surface, the second semiconductor region having a second conductivity type different from the first conductivity type,
a plurality of peripheral region trenches annularly surrounding the device region being formed in the main surface of the second semiconductor region.

2. The wide band gap semiconductor device according to claim 1, wherein
a bottom of each of the peripheral region trenches is located at the second semiconductor region side with respect to an interface between the first semiconductor region and the second semiconductor region.

3. The wide band gap semiconductor device according to claim 1, wherein
a bottom of each of the peripheral region trenches is located at the first semiconductor region side with respect to an interface between the first semiconductor region and the second semiconductor region.

4. The wide band gap semiconductor device according to claim 1, wherein
a dielectric layer covering the peripheral region trenches is formed on the main surface of the second semiconductor region.

5. The wide band gap semiconductor device according to claim 4, wherein
a material forming the dielectric layer includes at least one selected from the group consisting of silicon dioxide, polyimide, and silicon nitride.

6. The wide band gap semiconductor device according to claim 1, wherein
in the device region, a device trench is provided in the main surface of the semiconductor substrate,
a width of each of the peripheral region trenches at the main surface in a direction perpendicular to a direction in which the peripheral region trench extends is smaller than a width of the device trench at the main surface in a direction perpendicular to a direction in which the device trench extends, and
a depth of each of the peripheral region trenches in a direction perpendicular to the main surface is smaller than a depth of the device trench in the direction perpendicular to the main surface.

7. The wide band gap semiconductor device according to claim 1, wherein
in the device region, the semiconductor substrate includes the first semiconductor region having the main surface, a pair of third semiconductor regions spaced apart from and facing each other at the main surface, the third semiconductor regions having the second conductivity type, and a fourth semiconductor region having the first conductivity type in each of the pair of third semiconductor regions,
a width of each of the peripheral region trenches at the main surface in a direction perpendicular to a direction in which the peripheral region trench extends is smaller than spacing between the third semiconductor regions facing each other with the first semiconductor region interposed therebetween at the main surface, and
a depth of each of the peripheral region trenches in a direction perpendicular to the main surface is smaller than a depth of a bottom of each of the third semiconductor regions from the main surface.

8. The wide band gap semiconductor device according to claim 1, wherein
a sidewall of each of the peripheral region trenches is inclined with respect to the main surface.

9. The wide band gap semiconductor device according to claim 1, wherein
the first conductivity type is n type, and the second conductivity type is p type.
